(19) United States
(12) Patent Application Publication
(10) Pub. No.: US 2015/0129842 A1
(43) Pub. Date: May 14, 2015

(54) Method For Manufacturing Organic Electroluminescence Device And Organic Electroluminescence Device Manufactured With Same

(71) Applicant: Shenzhen China Star Optoelectronics Technology Co. Ltd., Shenzhen, Guangdong (CN)

(72) Inventor: Baixiang Han, Shenzhen (CN)

(73) Assignee: Shenzhen China Star Optoelectronics Technology Co. Ltd., Shenzhen, Guangdong (CN)

(21) Appl. No.: 14/235,727

(22) PCT Filed: Nov. 26, 2013
(86) PCT No.: PCT/CN2013/087881

§ 371 Date: Jan. 28, 2014

(30) Foreign Application Priority Data
Nov. 13, 2013 (CN) 201310566264.9

(51) Int. Cl. H01L 27/32; H01L 51/56; H01L 51/52; H01L 29/45; H01L 29/49; H01L 27/12; H01L 29/786

(52) U.S. Cl. CPC H01L 27/3258; H01L 27/1259; H01L 51/56; H01L 29/7869; H01L 29/45; H01L 29/4908; H01L 29/495; H01L 51/5237; H01L 2227/323; H01L 2251/306; H01L 2251/308; H01L 51/5206; H01L 51/5234
USPC 257/40; 438/23

(57) ABSTRACT

The present invention provides a method for manufacturing an organic electroluminescence device and an organic electroluminescence device manufactured with the same. The method includes (1) providing a substrate (20); (2) forming a first electrode (21) on the substrate (20); (3) forming a gate insulation layer (22) on the first electrode (21) and the substrate (20); (4) forming a second electrode (23) on the gate insulation layer (22), where the second electrode (23) includes a second metal layer (224) and a transparent conductive layer (222); (5) forming an oxide semiconductor layer (24) on the second electrode (23) and the gate insulation layer (22); (6) forming an organic planarization layer (25) on the oxide semiconductor layer (24) and the second electrode (23); (7) with the organic planarization layer (25) serving as a mask, etching the second metal layer (224) of the second electrode (23) to expose the transparent conductive layer (222) so as to form a transparent electrode (26).

### BACKGROUND OF THE INVENTION

1. Field of the Invention

The present invention relates to the field of flat panel displaying, and in particular to a method for manufacturing an organic electroluminescence device and an organic electroluminescence device manufactured with the method.

2. The Related Arts

A flat display device has various advantages, such as thin device body, low power consumption, and being free of radiation, and is thus of wide applications. The flat display devices that are currently available include liquid crystal displays (LCDs) and organic electroluminescence devices (OELDs), which are also referred to as organic light emitting diodes (OLEDs).

The known liquid crystal displays are generally backlighting liquid crystal displays, which include an enclosure, a liquid crystal display panel arranged in the enclosure, and a backlight module mounted inside the enclosure. The principle of operation of the liquid crystal display panel is that liquid crystal molecules are interposed between two parallel glass substrates and a driving voltage is applied to the glass substrates to control the rotation of the liquid crystal molecules so as to refract out the light from the backlight module to form an image.

Referring to FIG. 1, the conventional liquid crystal display panel generally comprises: a thin-film transistor (TFT) substrate 302, a color filter (CF) substrate 304 that is laminated on the thin-film transistor substrate 302, and a liquid crystal layer 306 arranged between the thin-film transistor substrate 302 and the color filter substrate 304. The thin-film transistor substrate 302 drives the liquid crystal molecules contained in the liquid crystal layer 306 to rotate in order to display a corresponding image.

The organic electroluminescence devices, which show the characteristics of self-illumination, high brightness, wide view angle, high contrast, flexibility, and low energy consumption, attract wide attention for serving as the next-generation display measures and gradually substitute the conventional liquid crystal displays for wide applications in various fields including mobile phone screens, computer monitors, and full-color television. The organic electroluminescence devices are different from the conventional liquid crystal displays in that they need no backlight and they use extremely thin coating layers of organic materials directly formed on the glass substrates so that when electrical currents flow therethrough, the organic material coating layers emit light.

The currently available organic electroluminescence devices are classified according to the driving methods used and include passive-matrix organic light emitting diodes (PMOLEDs) and active-matrix organic light emitting diodes (AMOLEDs). Referring to FIG. 2, a schematic view is given to show the structure of a conventional active-matrix organic light emitting diode, which comprises a substrate 100, a gate terminal 101 formed on the substrate 100, a gate insulation layer 102 formed on the gate terminal 101, a source/drain terminal 103 formed on the gate insulation layer 102, an oxide semiconductor layer 104 formed on the source/drain terminal 103, a first organic planarization layer 105, a transparent electrode 106 formed on the first organic planarization layer 105, and a second organic planarization layer 107 formed on the first organic planarization layer 105 and the transparent electrode 106. The transparent electrode 106 functions as an anode of the organic light emitting diode and is electrically connected, via a channel, to the source/drain terminal 103. An organic light emissive layer (not shown) and a cathode (not shown) are formed on the transparent electrode 106 through vapor deposition and is packaged with a packaging cover (not shown) to form the active-matrix organic light emitting diode. The manufacturing process requires, generally, 8 to 9 rounds of masking operation so that the manufacturing process is complicated and the cost is relatively high.

### SUMMARY OF THE INVENTION

An object of the present invention is to provide a method for manufacturing an organic electroluminescence device, which has a simple manufacturing process and can effectively lower down the manufacturing cost.

Another object of the present invention is to provide an organic electroluminescence device, which has a simple structure and a reduced thickness and a relatively low manufacturing cost.

To achieve the above objects, the present invention provides a method for manufacturing an organic electroluminescence device, which comprises the following steps:

(1) providing a substrate;

(2) forming a first metal layer on the substrate and patternizing the first metal layer to form a first electrode;

(3) forming a gate insulation layer on the first electrode and the substrate;

(4) sequentially forming a transparent conductive layer and second metal layer on the gate insulation layer and patternizing the second metal layer and the transparent conductive layer to form the second electrode, wherein the second electrode comprises the second metal layer and the transparent conductive layer located under the second metal layer;

(5) forming an oxide semiconductor layer on the second electrode and the gate insulation layer and patternizing the oxide semiconductor layer;

(6) forming an organic planarization layer on the oxide semiconductor layer and the second electrode and patternizing the organic planarization layer; and

(7) with the organic planarization layer serving as a mask, etching the second metal layer of the second electrode to expose the transparent conductive layer so as to form a transparent electrode.

The method for manufacturing an organic electroluminescence device further comprises:

(8) forming a spacer layer on the organic planarization layer;

(9) forming, through vapor deposition, an organic function layer and a cathode on the transparent electrode; and

(10) providing a packaging cover and carrying out packaging.

Step (1) comprises: providing the substrate and, after cleansing, forming a buffer layer on the substrate.

In step (2), the first metal layer is formed on the buffer layer.

The first metal layer and the second metal layer comprise at least one of aluminum and molybdenum; the transparent conductive layer comprises at least one of indium tin oxide and silver; and the substrate and the packaging cover are glass substrates.

The organic function layer comprises a hole transport layer formed on the transparent electrode, an organic emissive layer formed on the hole transport layer, and an electron transport layer formed on the organic emissive layer.

The present invention also provides a method for manufacturing an organic electroluminescence device, which comprises the following steps:

(1) providing a substrate;

(2) forming a first metal layer on the substrate and patternizing the first metal layer to form a first electrode;

(3) forming a gate insulation layer on the first electrode and the substrate;

(4) sequentially forming a transparent conductive layer and second metal layer on the gate insulation layer and patternizing the second metal layer and the transparent conductive layer to form the second electrode, wherein the second electrode comprises the second metal layer and the transparent conductive layer located under the second metal layer;

(5) forming an oxide semiconductor layer on the second electrode and the gate insulation layer and patternizing the oxide semiconductor layer;

(6) forming an organic planarization layer on the oxide semiconductor layer and the second electrode and patternizing the organic planarization layer; and

(7) with the organic planarization layer serving as a mask, etching the second metal layer of the second electrode to expose the transparent conductive layer so as to form a transparent electrode;

and further comprising:

(8) forming a spacer layer on the organic planarization layer;

(9) forming, through vapor deposition, an organic function layer and a cathode on the transparent electrode; and

(10) providing a packaging cover and carrying out packaging.

Step (1) comprises: providing the substrate and, after cleansing, forming a buffer layer on the substrate.

In step (2), the first metal layer is formed on the buffer layer.

The first metal layer and the second metal layer comprise at least one of aluminum and molybdenum; the transparent conductive layer comprises at least one of indium tin oxide and silver; and the substrate and the packaging cover are glass substrates.

The organic function layer comprises a hole transport layer formed on the transparent electrode, an organic emissive layer formed on the hole transport layer, and an electron transport layer formed on the organic emissive layer.

The present invention further provides an organic electroluminescence device, which comprises: a substrate, a first electrode formed on the substrate, a gate insulation layer formed on the first electrode and the substrate, a second electrode formed on the gate insulation layer, an oxide semiconductor layer formed on the second electrode and the gate insulation layer, an organic planarization layer formed on the oxide semiconductor layer and the second electrode, and a transparent electrode arranged on the gate insulation layer. The second electrode comprises a second metal layer and a transparent conductive layer located under the second metal layer. The transparent electrode is formed of the transparent conductive layer.

The organic electroluminescence device further comprises a buffer layer formed between the substrate and the first electrode, a spacer layer formed on the organic planarization layer, an organic function layer formed on the transparent electrode, a cathode formed on the organic function layer, and a packaging cover laminated to the substrate.

The organic function layer comprises a hole transport layer formed on the transparent electrode, an organic emissive layer formed on the hole transport layer, and an electron transport layer formed on the organic emissive layer.

The first electrode and the second metal layer comprise at least one of aluminum and molybdenum; the transparent conductive layer comprises at least one of indium tin oxide and silver; and the substrate and the packaging cover are glass substrates.

The efficacy of the present invention is that the present invention provides a method for manufacturing an organic electroluminescence device and an organic electroluminescence device manufactured with the method, wherein a second metal layer and a transparent conductive layer collectively constitute a second electrode so as to effectively reducing the impedance of the trace of the second electrode and improve the quality of the organic electroluminescence device. Further, an organic planarization layer can be used as a mask for etching the second metal layer of the second electrode in order to expose the transparent conductive layer for forming a transparent electrode. Compared to the known manufacturing processes, the manufacturing method of the present invention effectively simplify the manufacturing process, lower down the manufacturing cost, requires no formation of a second planarization layer, effectively reduce the thickness of the organic electroluminescence device, so as to facilitate the realization of thinning.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view showing the structure of a conventional liquid crystal display panel;

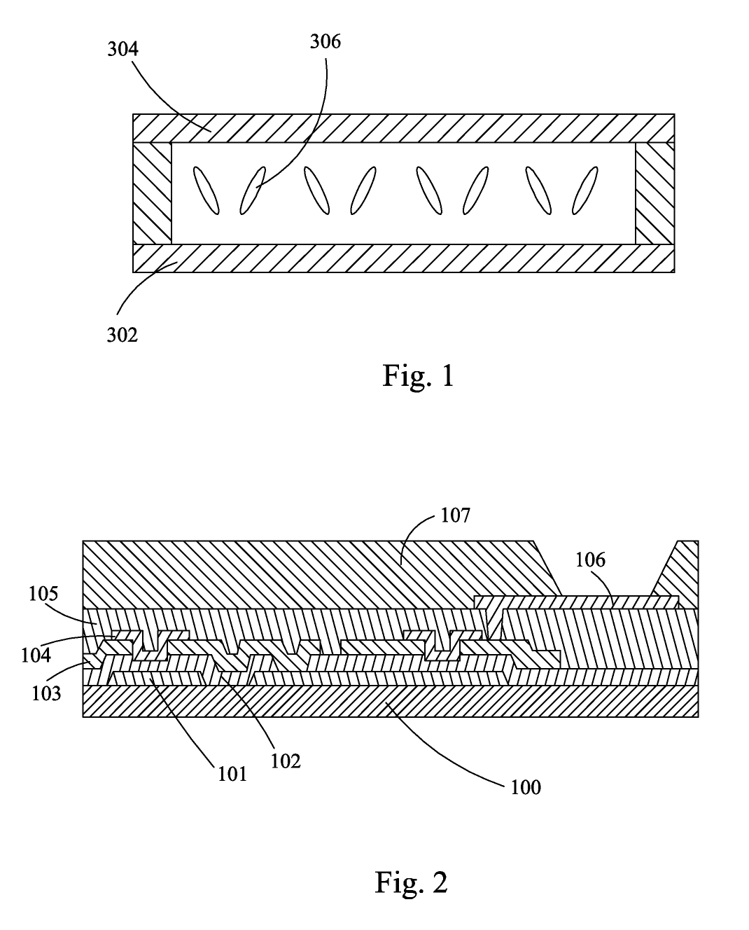

FIG. 2 is a schematic view showing a cross-sectional structure of a conventional active-matrix organic light emitting diode;

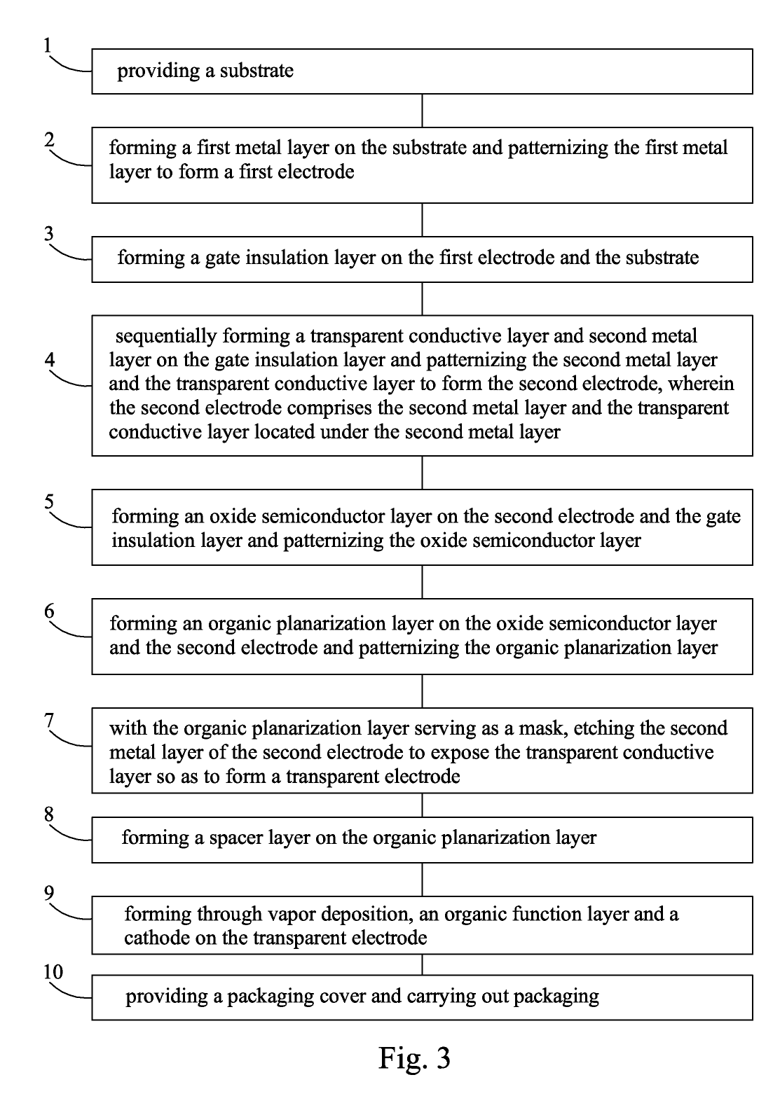

FIG. 3 is a flow chart illustrating a method for manufacturing an organic electroluminescence device according to the present invention;

FIGS. 4-9 are schematic views demonstrating the process of manufacturing the organic electroluminescence device according to the method of the present invention; and

FIG. 10 is a schematic view showing the layout of a pixel of the organic electroluminescence device according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

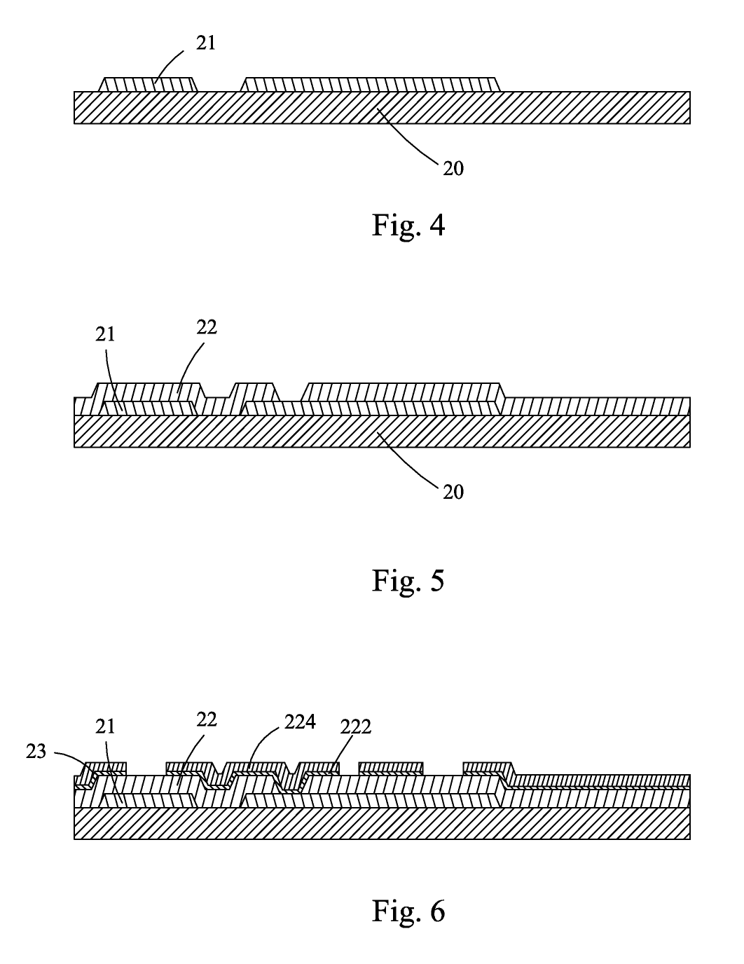

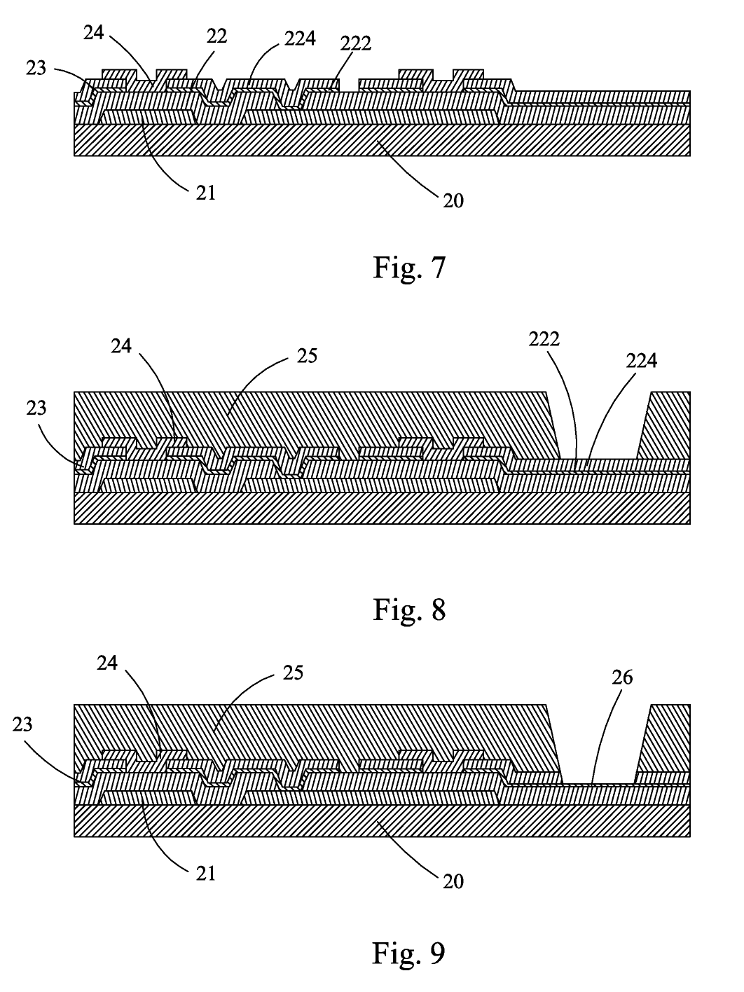

Referring to FIGS. 3-9, the present invention provides a method for manufacturing an organic electroluminescence device, which comprises the following steps:

Step 1: providing a substrate 20.

The substrate 20 is a transparent substrate, which can be a glass substrate or a plastic substrate. In the instant embodiment, the substrate 20 is a glass substrate.

Step 2: forming a first metal layer on the substrate 20 and patternizing the first metal layer to form a first electrode 21.

In the instant embodiment, the first metal layer comprises at least one of aluminum and molybdenum. The first electrode 21 is a gate terminal of which a specific manufacturing process is: forming the first metal layer on the substrate 20 through vapor deposition, forming a layer of a photo-sensitive material on the first metal layer, the photo-sensitive material being generally referred to as “photoresist”, and then allowing light to irradiate the photoresist by way of a mask to expose the photoresist. The mask carries the pattern of the first electrode 21 so that when the light passes through the mask to irradiate the photoresist, the photoresist is exposed in a selected manner and the pattern of the mask can be completely duplicated on the photoresist. Then, a proper developer is applied to remove a portion of the photoresist to have the photoresist showing a desired pattern.

Step 3: forming a gate insulation layer 22 on the first electrode 21 and the substrate 20.

The gate insulation layer 22 can be of a single-layered or multi-layered structure and comprises one of silicon oxide and silicon nitride or a combination thereof.

Step 4: sequentially forming a transparent conductive layer 222 and second metal layer 224 on the gate insulation layer 22 and patternizing the second metal layer 224 and the transparent conductive layer 222 to form the second electrode 23, wherein the second electrode 23 comprises the second metal layer 224 and the transparent conductive layer 222 located under the second metal layer 224.

In the instant embodiment, the transparent conductive layer 222 comprises at least one of indium tin oxide and silver or a combination thereof and the second metal layer 224 comprises at least one of aluminum and molybdenum. The second electrode 23 is a source/drain terminal. Since the second electrode 23 is formed collectively by the second metal layer 224 and the transparent conductive layer 222, compared to a conventional source/drain terminal that is completely formed of the second metal layer, the impedance of a trace thereof is relatively small so as to effectively improve the quality of the organic electroluminescence device of the present invention.

Step 5: forming an oxide semiconductor layer 24 on the second electrode 23 and the gate insulation layer 22 and patternizing the oxide semiconductor layer 24.

The oxide semiconductor layer 24 is formed in a similar way as that of the first electrode 21 described above so that repeated description will be omitted here.

Step 6: forming an organic planarization layer 25 on the oxide semiconductor layer 24 and the second electrode 23 and patternizing the organic planarization layer 25.

The organic planarization layer 25 functions to planarize the entire structure of the active thin-film transistor pixel array in order to facilitate subsequent operations to carry out.

Step 7: with the organic planarization layer 25 serving as a mask, etching the second metal layer 224 of the second electrode 23 to expose the transparent conductive layer 222 so as to form a transparent electrode 26.

In the instant embodiment, the transparent electrode 26 functions as the anode of the organic electroluminescence device of the present invention to excite the organic function layer to emit a desired light for displaying an image.

Compared to the known techniques, the present invention requires no separate manufacture of the transparent electrode 26 and saves one round of masking operation and needs no formation of a second organic planarization layer, so as to simplify the manufacturing process and effectively lower down the manufacturing cost.

Further, the method for manufacturing an organic electroluminescence device according to the present invention further comprises:

Step 8: forming a spacer (PS) layer (not shown) on the organic planarization layer 25.

Step 9: forming, through vapor deposition, an organic function layer (not shown) and a cathode (not shown) on the transparent electrode 26.

The organic function layer comprises a hole transport layer (HTL) formed on the transparent electrode 26, an organic emissive layer (EML) formed on the hole transport layer, and an electron transport layer (ETL) formed on the organic emissive layer.

Step 10: providing a packaging cover (not shown) and carrying out packaging.

In the instant embodiment, the packaging cover is a glass substrate, which is laminated on the substrate 20 by means of UV (Ultraviolet) curable resin or glass resin and is subjected to UV curing to achieve packaging of the organic electroluminescence device.

It is noted that Step 1 may further comprises: providing a substrate 20 and, cleansing, forming a buffer layer (not shown) on the substrate 20. In Step 2, the first metal layer is formed on the buffer layer.

Further, it is also feasible to form a protective layer (not shown) on the oxide semiconductor layer 24. The protective layer can be one of a silicon oxide layer and a silicon nitride layer or a combined layer thereof.

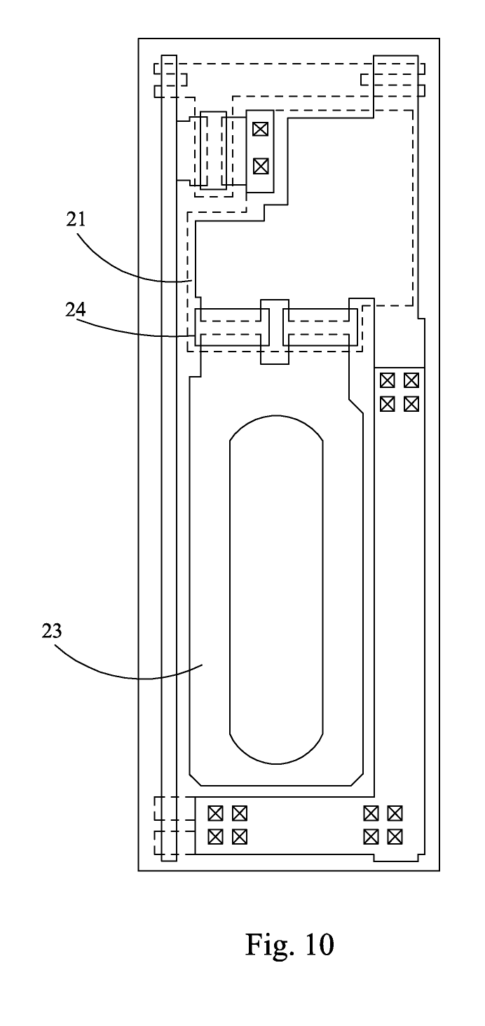

Referring to FIGS. 9 and 10, the present invention also provides an organic electroluminescence device, which comprises: a substrate 20, a first electrode 21 formed on the substrate 20, a gate insulation layer 22 formed on the first electrode 21 and the substrate 20, a second electrode 23 formed on the gate insulation layer 22, an oxide semiconductor layer 24 formed on the second electrode 23 and the gate insulation layer 22, an organic planarization layer 25 formed on the oxide semiconductor layer 24 and the second electrode 23, and a transparent electrode 26 arranged on the gate insulation layer 22. The second electrode 23 comprises a second metal layer 224 and a transparent conductive layer 222 located under the second metal layer 224. The transparent electrode 26 is formed of the transparent conductive layer 222. The first electrode 21 functions as a gate terminal and the second electrode 23 functions as a source/drain terminal. The gate terminal, the gate insulation layer 22, the source/drain terminal, and the oxide semiconductor layer 24 collectively form a thin-film transistor for driving the organic electroluminescence device.

Further, the organic electroluminescence device of the present invention further comprises: a buffer layer formed between the substrate 20 and the first electrode 21, a spacer layer formed on the organic planarization layer 25, an organic function layer formed on the transparent electrode 26, a cathode formed on the organic function layer, and a packaging cover laminated to the substrate 20.

Specifically, the organic function layer comprises a hole transport layer formed on the transparent electrode, an organic emissive layer formed on the hole transport layer, and an electron transport layer formed on the organic emissive layer.

In the instant embodiment, the first electrode 21 and the second metal layer 224 comprises at least one of aluminum and molybdenum. The transparent electrode 26 comprises at least one of indium tin oxide and silver. The substrate 20 and the packaging cover are both glass substrates.

In summary, the present invention provides a method for manufacturing an organic electroluminescence device and an organic electroluminescence device manufactured with the method, wherein a second metal layer and a transparent conductive layer collectively constitute a second electrode so as to effectively reducing the impedance of the trace of the second electrode and improve the quality of the organic electroluminescence device. Further, an organic planarization layer can be used as a mask for etching the second metal layer of the second electrode in order to expose the transparent conductive layer for forming a transparent electrode. Compared to the known manufacturing processes, the manufacturing method of the present invention effectively simplify the manufacturing process, lower down the manufacturing cost, requires no formation of a second planarization layer, effectively reduce the thickness of the organic electroluminescence device, so as to facilitate the realization of thinning.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing an organic electroluminescence device, comprising the following steps:
(1) providing a substrate;
(2) forming a first metal layer on the substrate and patternizing the first metal layer to form a first electrode;
(3) forming a gate insulation layer on the first electrode and the substrate;
(4) sequentially forming a transparent conductive layer and second metal layer on the gate insulation layer and patternizing the second metal layer and the transparent conductive layer to form the second electrode, wherein the second electrode comprises the second metal layer and the transparent conductive layer located under the second metal layer;
(5) forming an oxide semiconductor layer on the second electrode and the gate insulation layer and patternizing the oxide semiconductor layer;
(6) forming an organic planarization layer on the oxide semiconductor layer and the second electrode and patternizing the organic planarization layer; and
(7) with the organic planarization layer serving as a mask, etching the second metal layer of the second electrode to expose the transparent conductive layer so as to form a transparent electrode.

2. The method for manufacturing an organic electroluminescence device as claimed in claim 1 further comprising:
(8) forming a spacer layer on the organic planarization layer;
(9) forming, through vapor deposition, an organic function layer and a cathode on the transparent electrode; and
(10) providing a packaging cover and carrying out packaging.

3. The method for manufacturing an organic electroluminescence device as claimed in claim 1, wherein step (1) comprises: providing the substrate and, after cleansing, forming a buffer layer on the substrate.

4. The method for manufacturing an organic electroluminescence device as claimed in claim 3, wherein in step (2), the first metal layer is formed on the buffer layer.

5. The method for manufacturing an organic electroluminescence device as claimed in claim 2, wherein the first metal layer and the second metal layer comprise at least one of aluminum and molybdenum; the transparent conductive layer comprises at least one of indium tin oxide and silver; and
the substrate and the packaging cover are glass substrates.

6. The method for manufacturing an organic electroluminescence device as claimed in claim 2, wherein the organic function layer comprises a hole transport layer formed on the transparent electrode, an organic emissive layer formed on the hole transport layer, and an electron transport layer formed on the organic emissive layer.

7. A method for manufacturing an organic electroluminescence device, comprising the following steps:
(1) providing a substrate;
(2) forming a first metal layer on the substrate and patternizing the first metal layer to form a first electrode;
(3) forming a gate insulation layer on the first electrode and the substrate;
(4) sequentially forming a transparent conductive layer and second metal layer on the gate insulation layer and patternizing the second metal layer and the transparent conductive layer to form the second electrode, wherein the second electrode comprises the second metal layer and the transparent conductive layer located under the second metal layer;
(5) forming an oxide semiconductor layer on the second electrode and the gate insulation layer and patternizing the oxide semiconductor layer;
(6) forming an organic planarization layer on the oxide semiconductor layer and the second electrode and patternizing the organic planarization layer; and
(7) with the organic planarization layer serving as a mask, etching the second metal layer of the second electrode to expose the transparent conductive layer so as to form a transparent electrode;
and further comprising:
(8) forming a spacer layer on the organic planarization layer;
(9) forming, through vapor deposition, an organic function layer and a cathode on the transparent electrode; and
(10) providing a packaging cover and carrying out packaging.

8. The method for manufacturing an organic electroluminescence device as claimed in claim 7, wherein step (1) comprises: providing the substrate and, after cleansing, forming a buffer layer on the substrate.

9. The method for manufacturing an organic electroluminescence device as claimed in claim 8, wherein in step (2), the first metal layer is formed on the buffer layer.

10. The method for manufacturing an organic electroluminescence device as claimed in claim 7, wherein the first metal layer and the second metal layer comprise at least one of aluminum and molybdenum; the transparent conductive layer comprises at least one of indium tin oxide and silver; and the substrate and the packaging cover are glass substrates.

11. The method for manufacturing an organic electroluminescence device as claimed in claim 7, wherein the organic function layer comprises a hole transport layer formed on the transparent electrode, an organic emissive layer formed on the hole transport layer, and an electron transport layer formed on the organic emissive layer.

12. An organic electroluminescence device, comprising: a substrate, a first electrode formed on the substrate, a gate insulation layer formed on the first electrode and the substrate, a second electrode formed on the gate insulation layer, an oxide semiconductor layer formed on the second electrode and the gate insulation layer, an organic planarization layer formed on the oxide semiconductor layer and the second electrode, and a transparent electrode arranged on the gate insulation layer, the second electrode comprising a second metal layer and a transparent conductive layer located under the second metal layer, the transparent electrode being formed of the transparent conductive layer.

13. The organic electroluminescence device as claimed in claim 12 further comprising a buffer layer formed between the substrate and the first electrode, a spacer layer formed on the organic planarization layer, an organic function layer formed on the transparent electrode, a cathode formed on the organic function layer, and a packaging cover laminated to the substrate.

14. The organic electroluminescence device as claimed in claim 13, wherein the organic function layer comprises a hole transport layer formed on the transparent electrode, an organic emissive layer formed on the hole transport layer, and an electron transport layer formed on the organic emissive layer.

15. The organic electroluminescence device as claimed in claim 13, wherein the first electrode and the second metal layer comprise at least one of aluminum and molybdenum; the transparent conductive layer comprises at least one of indium tin oxide and silver; and the substrate and the packaging cover are glass substrates.
